(19) United States
(12) Patent Application Publication
(10) Pub. No.: US 2014/0175614 A1
(43) Pub. Date: Jun. 26, 2014

(54) WAFER STACKING STRUCTURE AND METHOD OF MANUFACTURING THE SAME

(71) Applicant: INDUSTRIAL TECHNOLOGY RESEARCH INSTITUTE, HSINCHU (TW)

(72) Inventors: CHUNG-CHIH WANG, HSINCHU CITY (TW); CHA-HSIN LIN, MIAOLI COUNTY (TW); TZU-KUN KU, HSINCHU CITY (TW)

(73) Assignee: INDUSTRIAL TECHNOLOGY RESEARCH INSTITUTE, HSINCHU (TW)

(21) Appl. No.: 13/723,129

(22) Filed: Dec. 20, 2012

(51) Int. Cl. H01L 21/768; H01L 23/48

(52) U.S. Cl. CPC H01L 21/76898; H01L 23/481
USPC 257/621; 438/107; 438/667

(57) ABSTRACT

A wafer stacking structure includes a first wafer and a second wafer. The first wafer includes a first through silicon via (TSV) opening and a first TSV filling portion formed in the first TSV opening and including a concave structure. The second wafer includes a second TSV opening and a second TSV filling portion formed in the second TSV opening and including a convex structure. A front surface of the first wafer faces a front surface of the second wafer, and the convex structure of the second TSV filling portion is inserted into the concave structure of the first TSV filling portion.

### TECHNICAL FIELD

This disclosure relates to a wafer stacking structure and a method of manufacturing the same.

### BACKGROUND

As miniaturization of semiconductor devices advances, three-dimensional (3D) wafer stacking technology is studied extensively. A Through Silicon Via (TSV) is one of the structures for enabling 3D wafer stacking. The TSV is an electrical connection passing through a silicon wafer or die. When the TSV is combined with solder humps, wafers or dies may be stacked, achieving high-density interconnections.

However, additional processes may be required in order to form the solder bumps, and to align the solder bumps with the TSVs. These additional processes undesirably increase complexity and cost of the manufacturing process of the semiconductor devices.

### SUMMARY

According to a first embodiment of the disclosure, there is provided a method of manufacturing a wafer stacking structure. The method includes: forming a first through silicon via (TSV) opening in a first wafer; filling a first conductive material in the first TSV opening to form a first TSV filling portion having a concave structure; forming a second TSV opening in a second wafer; filling a second conductive material in the second TSV opening to form a second TSV filling portion having a convex structure; and stacking the first wafer with the second wafer, with the convex structure being inserted into the concave structure, and the first TSV filling portion being electrically connected with the second TSV filling portion.

According to a second embodiment of the disclosure, there is provided a wafer stacking structure including a first wafer and a second wafer. The first wafer includes a first through silicon via (TSV) opening penetrating from a front surface to a back surface of the first wafer, and a first TSV filling portion formed inside the first TSV opening and including a concave structure on a front surface of the first TSV filling portion. The second wafer includes a second TSV opening penetrating from a front surface to a back surface of the second wafer, and a second TSV filling portion formed inside the second TSV opening and including a convex structure on a front surface of the second TSV filling portion. In the wafer stacking structure, the front surface of the first wafer faces the front surface of the second wafer, and the convex structure of the second TSV filling portion is inserted into the concave structure of the first TSV filling portion.

According to a third embodiment of the disclosure, there is provided a method of manufacturing a wafer. The method includes forming a through silicon via (TSV) opening on the wafer, and filling a conductive material in the opening by electroplating to form a TSV filling portion having a concave structure or a convex structure.

It is to be understood that both the foregoing general description and the following detailed description are exemplary and explanatory only and are not restrictive of the disclosure, as claimed.

### BRIEF DESCRIPTION OF THE DRAWINGS

The accompanying drawings, which are incorporated in and constitute a part of this specification, illustrate embodiments consistent with the disclosure and, together with the description, serve to explain the principles of the disclosure.

FIGS. 1A-1C are cross-sectional views of a first wafer in a manufacturing process of a semiconductor device, according to an exemplary embodiment.

FIGS. 2A-2C are cross-sectional views of a second wafer in a manufacturing process of a semiconductor device, according to an exemplary embodiment.

FIG. 3 is a cross-sectional view of a wafer stacking structure, according to an exemplary embodiment.

FIG, 4 is a cross-sectional view of a wafer stacking structure, according to another exemplary embodiment.

FIGS. 5A and 5B are cross-sectional views of a first wafer and a second wafer, respectively, in a manufacturing process of a semiconductor device, according to another exemplary embodiment.

FIG. 6 is a cross-sectional view of a wafer stacking structure, according to another exemplary embodiment.

FIGS. 7A-7C are cross-sectional views of a first wafer in a manufacturing process of a semiconductor device, according to another exemplary embodiment.

FIGS. 8A-8C are cross-sectional views of a second wafer in a manufacturing process of a semiconductor device, according to another exemplary embodiment.

FIG. 9 is a cross-sectional view of a wafer stacking structure, according to an exemplary embodiment.

FIGS. 10A and 10B are cross-sectional views of a first wafer and a second wafer, respectively, in a manufacturing process of a semiconductor device, according to a further exemplary embodiment.

FIG. 11 is a cross-sectional view of a first wafer and a second wafer, according to another exemplary embodiment.

### DESCRIPTION OF THE EMBODIMENTS

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of systems and methods consistent with aspects related to the disclosure as recited in the appended claims.

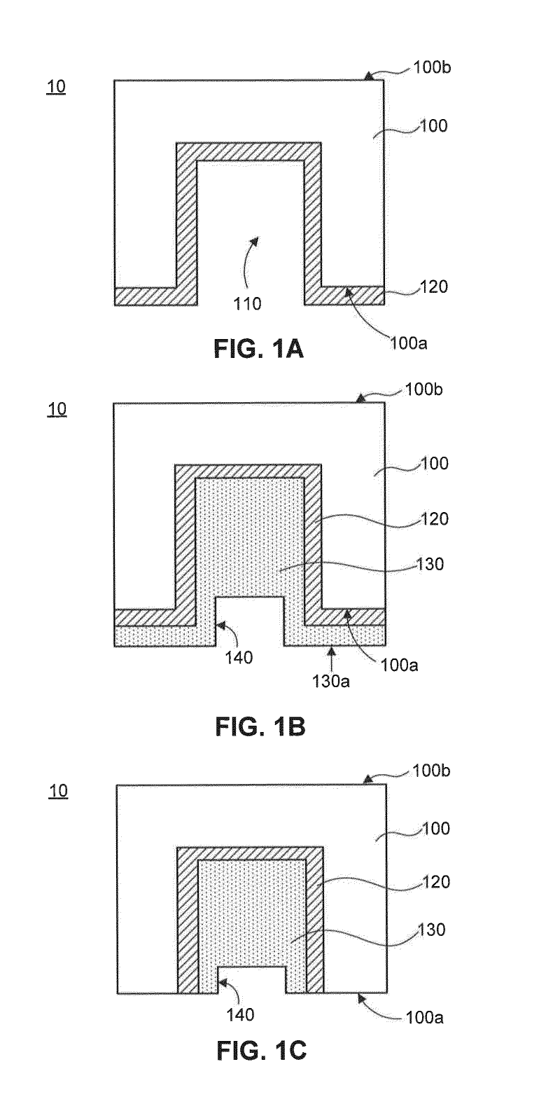

FIGS. 1A-1C are cross-sectional views of a first wafer 10 in a manufacturing process of a semiconductor device, according to an exemplary embodiment.

Referring to FIG. 1A, the first wafer 10 is constructed with a first substrate 100 having a front surface 100a and a back surface 100b, a first TSV opening 110 and a first barrier layer 120 formed on the front surface 100a of the first substrate 100. The first substrate 100 may be a semiconductor substrate made of, for example, silicon (Si), gallium arsenide (GaAs), gallium arsenide-phosphide (GaAsP), indium phosphide (InP), gallium aluminum arsenic (GaAlAs), indium gallium, phosphide (InGaP), or the like. Although not shown in FIG. 1A, the first wafer 10 may be constructed with at least one integrated circuit component on at least one of the front surface 100a and the back surface 100b of the substrate 100. Although the first substrate 100 in FIG. 1A is illustrated as composed of a single, homogeneous material, the embodiment is not limited thereto, and the first substrate 100 may include an additional layer, such as a low dielectric constant film formed on at least one of the front surface 100a and the back surface 100b of the first substrate 100.

The first TSV opening 110 is formed on the front surface 100a of the first substrate 100 in a region in which a TSV filling portion is to be formed later. The first TSV opening 110 may be formed by, for example, wet etching, or reactive ion etching (RIE). The first TSV opening 110 may be formed with a predetermined depth such that the first TSV opening 110 does not pass through the first wafer 10. Although in the exemplary embodiment shown in FIG. 1A, one first TSV opening 110 is formed, more than one TSV opening may be formed in the first substrate 100.

The first barrier layer 120 is deposited on the first substrate 110. The first barrier layer 120 includes a first portion covering bottom and side walls of the first TSV opening 110, and a second portion extending over and covering the front surface 100a of the first substrate 100. The first barrier layer 120 prevents conductive material, to be formed later, from diffusing into the first substrate 100. Materials for the first barrier layer 120 include titanium (Ti), tantalum (Ta), titanium nitride (TiN), cobalt-tungsten-phosphorus alloy (CoWP), or combinations thereof. The first barrier layer 120 may be formed by, for example, chemical vapor deposition (CVD), or physical vapor deposition (PVD). In this embodiment, the first barrier layer 120 is made of Ta in order to facilitate a chemical mechanical polishing (CMP) process to be performed later. Although not shown in FIG. 1A, a seed layer may be further formed on the first barrier layer 120 to facilitate a subsequent electroplating process to deposit conductive material. The seed layer may be made of, for example, copper (Cu) or tungsten (W).

Referring to FIG. 1B, a conductive material is filled in the first TSV opening 110 to form a first TSV filling portion 130. The conductive material may be, for example, copper (Cu), silver (Ag), gold (Au), tungsten (W), doped semiconductors such as polysilicon, or combinations thereof. The first TSV filling portion 130 may be formed by an electroplating process. In the exemplary embodiment, a concave structure 140 is formed on a front surface 130a of the first TSV filling portion 130. The concave structure 140 may be formed by controlling at least one of the process parameters of the electroplating process, such as plating time, plating current, and plating solution. In one exemplary embodiment, the electroplating process may be conducted for less than 90 minutes to form the first TSV filling portion 130 made of Cu and having a concave structure in the first TSV opening 110, with the first TSV opening 110 having a diameter of 10 μm and a depth of 100 μm. During the electroplating process, the conductive material of the first TSV filling portion 130 may extend to cover the second portion of the first barrier layer 120 covering the front surface 100a of the first substrate 100. Although not shown in FIG. 1B, a redistribution layer may be formed on the front surface 100a of the first substrate 100, electrically connecting the first TSV filling portion 130 with an integrated circuit component formed on the first wafer 10. The redistribution layer may be made of the same material as that of the first TSV filling portion 130.

Referring to FIG. 1C, the front surface 100a of the first substrate 100 may be polished by a CMP process. The CMP process performed in this step is the CMP process mentioned earlier that is facilitated by the first barrier layer 120 made of Ta. As a result of the CMP process, portions of the first barrier layer 120 and the conductive material covering the front surface 100a of the substrate 100 are removed to expose the front surface 100a of the substrate 100. However, the concave structure 140 is preserved, although its depth is reduced, as shown in FIG. 1C.

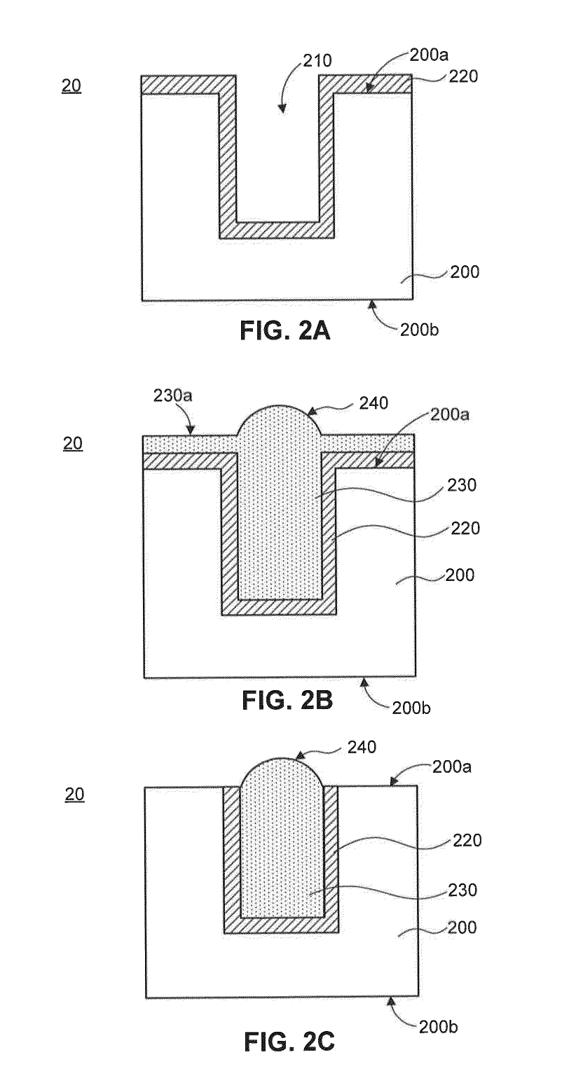

FIGS. 2A-2C are cross-sectional views of a second wafer 20 in a manufacturing process of a semiconductor device, according to an exemplary embodiment.

Referring to FIG. 2A, the second wafer 20 may be constructed with a second substrate 200 having a front surface 200a and a back surface 200b, a second TSV opening 210 and a second barrier layer 220 formed on the front surface 200a of the second substrate 200. The material, the structure, and the method of manufacturing the second wafer 20 shown in FIG. 2A are the same as those of the first wafer 10 shown in FIG. 1A, except that the second barrier layer 220 of the second wafer 20 may be made of CoWP, in order to facilitate a wet etching process to be performed later. The second TSV opening 210 of the second wafer 20 is positioned for subsequent alignment with the first TSV opening 110 of the first wafer 10 to enable stacking of the first wafer 10 and the second wafer 20.

Referring to FIG. 213, a conductive material is filled in the second TSV opening 210 to form a second TSV filling portion 230. The material and the manufacturing method of the second TSV filling portion 230 may be the same as those of the first TSV filling portion 130, except that, a convex structure 240 is formed on a front surface 230a of the second TSV filling portion 230. The convex structure 240 may be formed by controlling at least one of the process parameters of the electroplating process, such as plating time, plating current, and plating solution. In one embodiment, the time for filling the first TSV opening 110 to form the first TSV filling portion 130 having the concave structure 140 is shorter than the time for filling the second TSV opening 210 to form the second TSV filling portion 230 having the convex structure 240. During the electroplating process, the conductive material of the second TSV filling portion 230 may extend to cover the front surface 200a of the second substrate 200.

Referring to FIG. 2C, the second wafer 20 is etched by a wet etching process in, for example, a bath including copper sulphate monohydrate (CuSO₄) and hydrogen peroxide (H₂O₂). The wet etching process performed in this step is the wet etching process mentioned earlier that is facilitated by the second barrier layer 220 made of CoWP. As a result, portions the second barrier layer 220 and the second TSV filling portion 230 covering the top surface of the substrate 200 are removed to expose a top surface 200a of the substrate 200. However, the convex structure 240 is preserved, as shown in FIG. 2C. After the wet etching process, the height of the convex structure 240 relative to the peripheral regions surrounding the convex structure 240 is not reduced, because both the peripheral regions and the convex structure 240 are etched during the wet etching process.

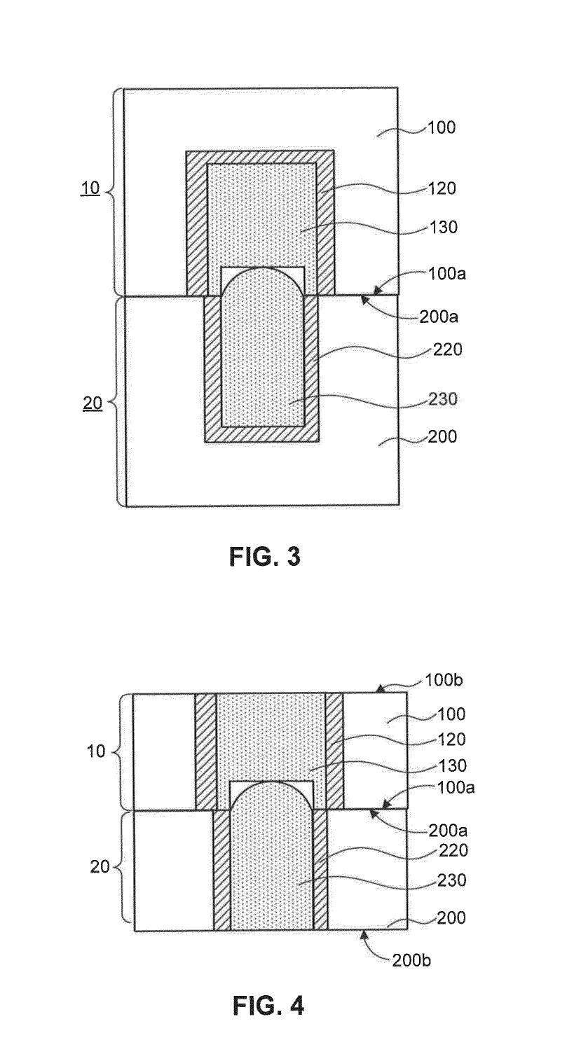

FIG. 3 is a cross-sectional view of a wafer stacking structure including the first wafer 10 and the second wafer 20 after further processing steps.

Referring to FIG. 3, the wafer stacking structure includes the first wafer 10 and the second wafer 20 vertically stacked together such that the front surface 100a of the first wafer 10 faces the front surface 200a of the second wafer 20, the first TSV filling portion 130 and the second TSV filling portion 230 are aligned with and contact each other, and the convex structure 240 of the second wafer 20 is inserted into the concave structure 140 of the first wafer 10. In the embodiment, the top surface 100a of the first wafer 100 contacts the top surface 200a of the second wafer 200. The first wafer 10 and the second wafer 20 are bonded together by, for example, a wafer bonding process such as thermal compression. As a result, the first TSV filling portion 130 of the first wafer 10 and the second TSV filling portion 230 of the second wafer 20 are electrically and physically connected with each other.

In one exemplary embodiment, a size of a cross-sectional area of the first TSV opening 110 may be larger than a size of a cross-sectional area of the second TSV opening 210. In another exemplary embodiment, the size of the cross-sectional area of the first TSV opening 110 may be the same as the size of the cross-sectional area of the second TSV opening 210.

In one exemplary embodiment, a size of a minimum cross-sectional area of the concave structure 140 may be larger than a size of a maximum cross-sectional area of the convex structure 240. In this way, when the first wafer 10 and the second wafer are stacked together, the convex structure 240 of the second TSV filling portion 230 is easily inserted into the concave structure 140 of the first TSV filling portion 130.

In another exemplary embodiment, the size of the minimum cross-sectional area of the concave structure 140 may be the same as the size of the maximum cross-sectional area of the convex structure 240.

FIG. 4 is a cross-sectional view of a wafer stacking structure, after further processing steps.

Referring to FIG. 4, after the first wafer 10 and the second wafer 20 are stacked together as shown in FIG. 3, at least one of a grinding process and an etching process is performed on the back surfaces 100b and 200b of the first wafer 10 and the second wafer 20, respectively. As a result, the TSV filling portions 130 and 230 are exposed on back surfaces 100b and 200b of, and thereby penetrate through, the first and second wafers and 10 and 20, respectively.

Although in the exemplary embodiment, the at least one of the grinding process and the etching process is performed after the wafer stacking structure is formed, the grinding process and/or the etching process may instead be performed before the wafer stacking structure is formed, and after the TSV filling portion is formed.

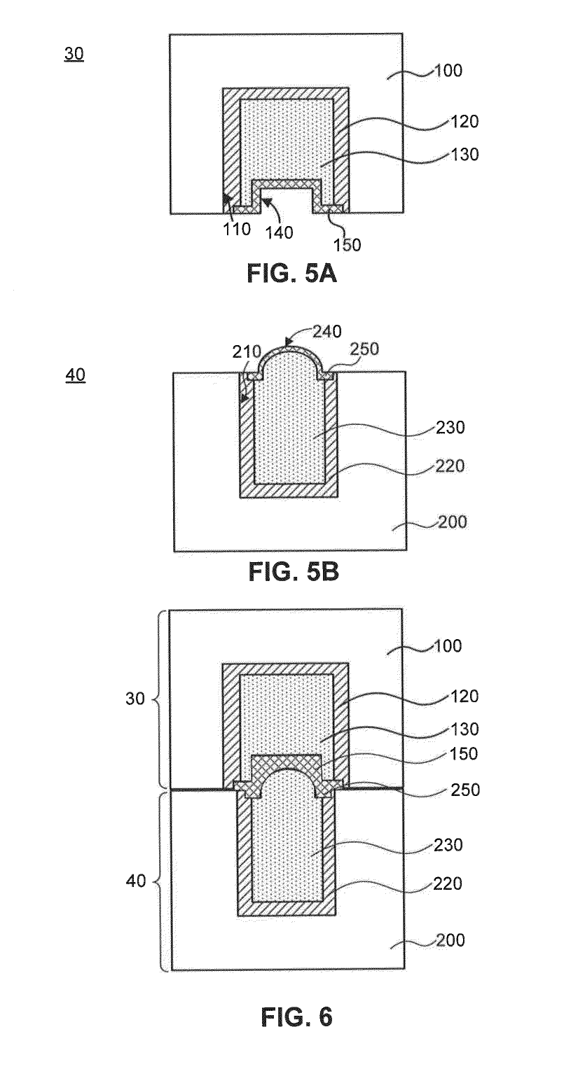

FIGS. 5A and 5B are cross-sectional views of a first wafer 30 and a second wafer 40, respectively, in a manufacturing process of a semiconductor device, according to another exemplary embodiment.

Referring to FIG. 5A, the first wafer 30 is constructed with the first substrate 100, the first barrier layer 120, and the first TSV filling portion 130 having the concave structure 140. The first wafer 30 is further constructed with a first solder layer 150 covering a front surface of the first TSV filling portion 130, and bottom and side walls of the concave structure 140 of the first TSV filling portion 130. The first solder layer 150 may include, for example, tin (Sn), nickel-gold alloy (NiAu), nickel-palladium-gold alloy (NiPdAu), tin-silver alloy (SnAg), or the like. The first solder layer 150 may be formed by, for example, electroless plating.

Referring to FIG. 5B, the second wafer 40 is constructed with the second substrate 200, the second barrier layer 220, and the second TSV filling portion 230 having the convex structure 240. The second wafer 40 is further constructed with a second solder layer 250 covering a front surface of the second TSV filling portion 230 including a front surface of the convex structure 240. The material and the manufacturing method of the second solder layer 250 may be the same as those of the first solder layer 150.

FIG. 6 is a cross-sectional view of a wafer stacking structure including the first wafer 30 and the second wafer 40, after further processing steps.

Referring to FIG. 6, the wafer stacking structure includes the first wafer 30 and the second wafer 40 stacked and bonded together by, for example, soldering. The first TSV filling portion 130 of the first wafer 30 and the second TSV filling portion 230 of the second wafer 40 are aligned and electrically connected with each other through the first solder layer 150 and the second solder layer 250. The first solder layer 150 and the second solder layer 250 may increase the contact area and the contact strength between the TSV filling portions 130 and 230, relative to the wafer stacking structure shown in FIG. 3 without the solder layers. In addition, when the first wafer 30 and the second wafer 40 are bonded together by soldering, an extra amount of the solder may be filled inside the concave structure 140 of the first TSV filling portion 130, so as to prevent solder spilling outside the TSV filling portions 130 and 230.

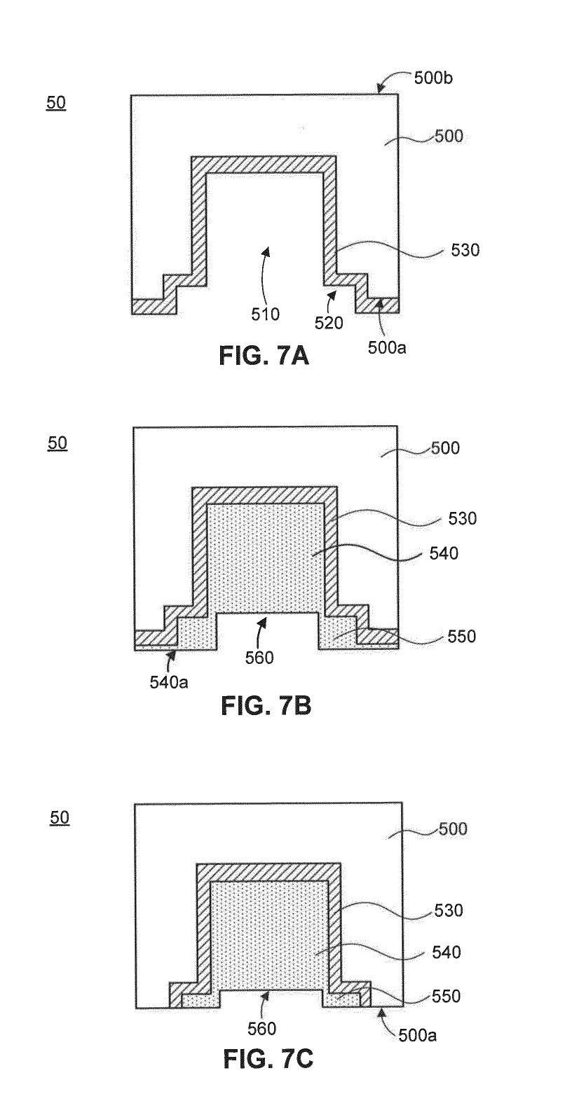

FIGS. 7A-7C are cross-sectional views of a first wafer 50 in a manufacturing process of a semiconductor device, according to another exemplary embodiment.

Referring to FIG, 7A, the first wafer 50 is constructed with a first substrate 500 having a front surface 500a and a back surface 500b, a first TSV opening 510 and a first bonding pad opening 520 formed on the front surface 500a of the first substrate 500. The first TSV opening 510 and the first bonding pad opening 520 may optionally be substantially concentric. The first bonding pad opening 520 surrounds the first TSV opening 510. Since the first bonding pad opening 520 surrounds the first TSV opening 510, a periphery of the first bonding pad opening 520 defines a cross-sectional area larger than the cross-sectional area of the first TSV opening 510. The depth of the first TSV opening 510 is larger than the depth of the first bonding pad opening 520. The first substrate 500 may include a first barrier layer 530 deposited on the front surface 500a of the substrate 500, covering the front surface 500a of the substrate 500, and bottoms and side walls of the first TSV opening 510 and the first bonding pad opening 520. The first barrier layer 530 may be made of Ta in order to facilitate a CMP process to be performed later. A seed layer (not shown) may be further formed on the first barrier layer 530.

Referring to FIG. 7B, a conductive material is filled in the first TSV opening 510 and the first bonding pad opening 520, to form a first TSV filling portion 540 and a first bonding pad 550. The conductive material may be made of, for example, copper (Cu), silver (Ag), gold (Au), tungsten (W), doped semiconductors such as polysilicon, or combinations thereof. The first TSV filling portion 540 and the first bonding pad 550 may be formed by an electroplating process. The conductive material may extend to cover the portion of the first barrier layer 530 covering the front surface 500a of the first substrate 500. In a manner similar to that described above for forming the concave structure 140 shown in FIG. 1B, a concave structure 560 is formed on a front surface 540a of the first TSV filling portion 540 by controlling the time of the electroplating process.

Referring to FIG. 7C, the front surface 500a of the first wafer 50 is polished by a CMP process. The CMP process performed in this step is the CMP process mentioned earlier that is facilitated by the first barrier layer 530 made of Ta. As a result, portions of the first barrier layer 530 and the conductive material covering the front surface 500a of the first substrate 500 are removed to expose the front surface 500a of the first substrate 500. However, the concave structure 560 is preserved, although reduced in depth.

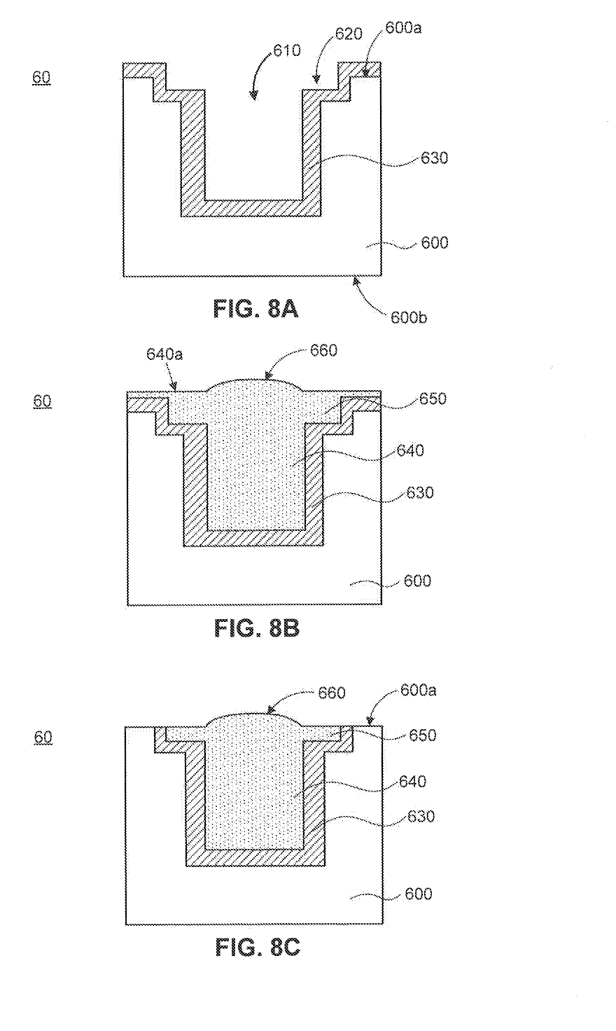

FIGS. 8A-8C are cross-sectional views of a second wafer 60 in a manufacturing process of a semiconductor device, according to an exemplary embodiment.

Referring to FIG. 8A, the second wafer 60 is constructed with a second substrate 600 having a front surface 600a and back surface 600b, a second TSV opening 610, a second bonding pad opening 620, and a second barrier layer 630 formed on the front surface 600a of the second substrate 600. The material, the structure, and the method of manufacturing the second wafer 60 shown in FIG. 8A are the same as those of the first wafer 50 shown in FIG. 7A, except that the barrier layer 630 of the second wafer 60 may be made of CoWP in order to facilitate a wet etching process to be performed later.

Referring to FIG. 8B, a conductive material is filled in the second TSV opening 610 and the second bonding pad opening 620 to form a second TSV filling portion 640 and a second bonding pad 650. The material and the manufacturing method of the second TSV filling portion 640 and the second bonding pad 650 may be the same as those of the first TSV portion 540 and the first bonding pad 550, except that, by controlling the time of the electroplating process for forming the second TSV filling portion 640, a convex structure 660 is formed on a front surface 640a of the second TSV filling portion 640. Exemplary parameters for forming the convex structure 660 are substantially the same as described above for forming the convex structure 240 shown in FIG. 2B. The conductive material of the second TSV filling portion 640 may extend to cover the portion of the second barrier layer 630 covering the front surface 600a of the second substrate 600.

Referring to FIG. 8C, the second wafer 60 may be etched by a wet etching process in, for example, a bath including CuSO₄ and H₂O₂. The wet etching process performed in this step is the wet etching process mentioned earlier that is facilitated by the second barrier layer 630 made of CoWP. As a result, portions of the barrier layer 630 and the conductive material covering the front surface 600a of the substrate 600 are removed to expose the front surface 600a of the substrate 600. However, the convex structure 660 is preserved, as shown in FIG. 8C. After the wet etching process, the height of the convex structure 660 relative to the peripheral regions surrounding the convex structure 660 is not reduced, because both the peripheral regions and the convex structure 660 are etched during the wet etching process.

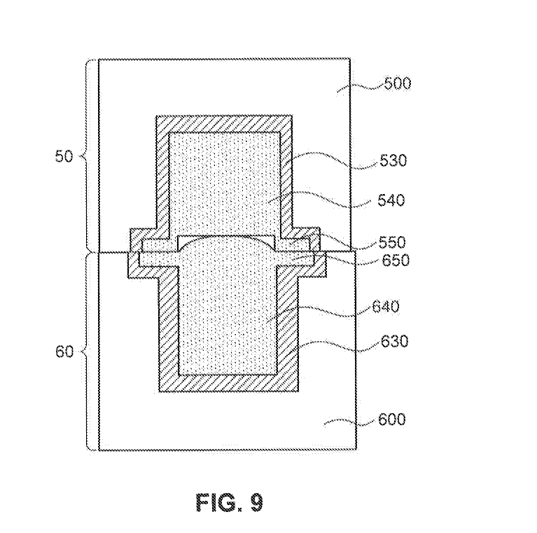

FIG. 9 is a cross-sectional view of a wafer stacking structure including the first wafer 50 and the second wafer 60, after further processing steps,

Referring to FIG. 9, the wafer stacking structure includes the first wafer 50 and the second wafer 60 vertically stacked together, such that the front surface 500a of the first wafer 50 faces the front surface 600a of the second wafer 60, the first TSV filling portion 540 and the first bonding pad 550 of the first wafer 50 are respectively aligned with the second TSV filling portion. 640 and the second bonding pad 650 of the second wafer 60, and the convex structure 660 of the second wafer 60 is inserted into the concave structure 560 of the first wafer 50. In addition, the top surface 500a of the first wafer 50 contacts the top surface 600a of the second wafer 60. Then, the first wafer 50 and the second wafer 60 are bonded together by, for example, thermal compression, such that the first filling portion 540 and the first bonding pad 550 of the first wafer 50 and the second filling portion 640 and the second bonding pad 650 of the second wafer 60 physically contact and electrically connect with each other.

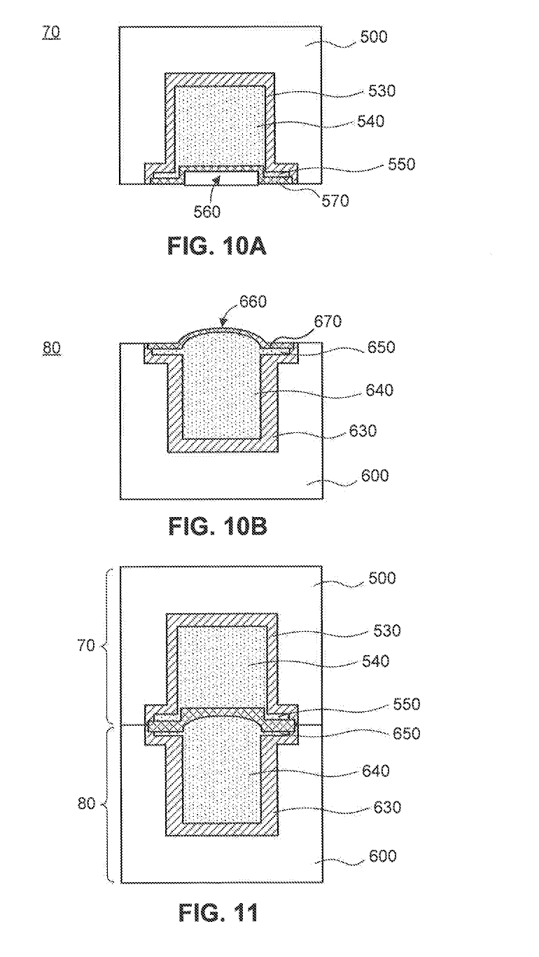

FIGS. 10A and 10B are cross-sectional views of a first wafer 70 and a second wafer 80, respectively, in a manufacturing process of a semiconductor device, according to a further exemplary embodiment.

Referring to FIG. 10A, the first wafer 70 is constructed with the first substrate 500, the first barrier layer 530, the first TSV filling portion 540 having the concave structure 560, and the first bonding pad 550. However, the first wafer 70 is further constructed with a first solder layer 570 covering front surfaces of the first TSV filling portion 540 and the bonding pad 550, and bottom and inner walls of the concave structure 560. The first solder layer 570 is formed by, for example, electroless plating.

Referring to FIG. 10B, the second wafer 80 is constructed with the second substrate 600, the second barrier layer 630, the second TSV filling portion 640 having the convex structure 660, and the second bonding pad 650. The second wafer 80 is further constructed with a second solder layer 670 covering front surfaces of the second TSV filling portion 640 and the second bonding pad 650 including a front surface of the convex structure 660.

FIG. 11 is a cross-sectional view of a wafer stacking structure including the first wafer 70 and the second wafer 80, after further processing steps.

Referring to FIG. 11, the wafer stacking structure includes the first wafer 70 and the second wafer 80 vertically stacked and bonded together by, for example, soldering. The first TSV filling portion 540 and the first bonding pad 550 of the first wafer 70 are respectively aligned and electrically connected with the second TSV filling portion 640 and the second bonding pad 650 of the second wafer 80 through the first solder layer 570 and the second solder layer 670. The first solder layer 570 and the second solder layer 670 increase the contact area and the contact strength between the first TSV filling portion 540 and the first bonding pad 550 of the first wafer 70 and the second TSV filling portion 640 and the second bonding pad 650 of the second wafer 80.

Although the first wafer and the second wafer are used as an example to illustrate the various processes of wafer stacking in various embodiments, in practice, the structures to be bonded may be either wafers or integrated circuit dies.

Although in the embodiments the first wafer 10 of FIG. 1C is stacked with the second wafer 20 of FIG. 2C, the first wafer 30 of FIG. 5A is stacked with the second wafer 40 of FIG, 5B, the first wafer 50 of FIG. 7C is stacked with the second wafer 60 of FIG. 8C, and the first wafer 70 of FIG. 10A is stacked with the second wafer 80 of FIG. 10B, the disclosure is not so limited. That is, each one of the first wafers 10, 30, 50, and 70 may be stacked with any one of the second wafers 20, 40, 60, and 80.

Although in the wafer stacking structures in the embodiments, the first wafer having the concave structure is disposed on top of the second wafer having the convex structure, the disclosure is not so limited. That is, the first wafer having the concave structure may be disposed under the second wafer having the convex structure.

Other embodiments will be apparent to those skilled in the art from consideration of the specification and practice of the embodiments disclosed herein. The scope of the disclosure is intended to cover any variations, uses, or adaptations of the disclosure following the general principles thereof and including such departures from the disclosure as come within known or customary practice in the art. It is intended that the specification and examples be considered as exemplary only, with a true scope and spirit of the disclosure being indicated by the following claims.

It will be appreciated that the disclosure is not limited to the exact construction that has been described above and illustrated in the accompanying drawings, and that various modifications and changes can be made without departing from the scope thereof. It is intended that the scope of the disclosure only be limited by the appended claims.

What is claimed is:

1. A method of manufacturing a wafer stacking structure, the method comprising;
forming a first through silicon via (TSV) opening in a first wafer;
filling a first conductive material in the first TSV opening to form a first TSV filling portion having a concave structure;
forming a second TSV opening in a second wafer;
filling a second conductive material in the second TSV opening to form a second TSV filling portion having a convex structure; and
stacking the first wafer with the second wafer, with the convex structure being inserted into the concave structure, and the first TSV filling portion being electrically connected with the second TSV filling portion.

2. The method of claim 1, further comprising:
forming a solder layer on at least one of the first TSV filling portion and the second TSV filling portion.

3. The method of claim 1, further comprising:
forming a bonding pad surrounding at least one of the first and second TSV filling portions.

4. The method of claim 3, wherein the forming of the bonding pad surrounding the at least one of the first and second TSV filling portions comprises:
forming a bonding pad opening surrounding a TSV opening corresponding to the at least one of the first and second TSV filling portions, prior to the forming of the at least one of the first and second. TSV filling portions; and
filling the first and second conductive materials in the bonding pad opening to form the bonding pad while forming the at least one of the first and second TSV filling portions, respectively.

5. The method of claim 3, further comprising:
forming a solder layer on the bonding pad.

6. The method of claim 1, wherein:
the filling of the first conductive material in the first TSV opening and the second conductive material in the second TSV opening is performed by electroplating, and
the time for filling the first TSV opening is shorter than the time for filling the second TSV opening.

7. The method of claim 6, further comprising:
farming a barrier layer on a front surface of the first wafer prior to the forming of the first TSV filling portion, the barrier layer including a first portion covering bottom and side walls of the first TSV opening, and a second portion extending over the front surface of the first wafer; and
removing the second portion of the barrier layer by polishing the front surface of the first wafer after the forming of the first TSV filling portion and prior to the stacking of the first wafer with the second wafer.

8. The method of claim 6, further comprising:
forming a barrier layer on a front surface of the second wafer prior to the forming of the second TSV filling portion, the barrier layer including a first portion covering bottom and side walls of the second TSV opening, and a second portion extending over the front surface of the second wafer; and
removing the second portion of the barrier layer by wet etching the second wafer after the forming of the second TSV filling portion and prior to the stacking of the first wafer with the second wafer.

9. The method of claim 1, further comprising:
exposing the first or second TSV filling portion through a back surface of the first wafer or the second wafer, respectively.

10. The method of claim 1, wherein:
a size of a minimum cross-sectional area of the concave structure is larger than or the same as a size of a maximum cross-sectional area of the convex structure.

11. The method of claim 1, wherein the stacking includes:
stacking the first wafer having the concave structure on top of the second wafer having the convex structure.

12. The method of claim 1, wherein the stacking includes:
stacking the second wafer having the convex structure on top of the first wafer having the concave structure.

13. A wafer stacking structure, comprising:
a first wafer including:
a first through silicon via (TSV) opening penetrating from a front surface to a back surface of the first wafer; and
a first TSV filling portion formed inside the first TSV opening and including a concave structure on a front surface of the first TSV filling portion; and
a second wafer including:
a second TSV opening penetrating from a front surface to a back surface of the second wafer; and
a second TSV filling portion formed inside the second TSV opening and including a convex structure on a front surface of the second TSV filling portion,
the front surface of the first wafer facing the front surface of the second wafer, and the convex structure of the second TSV filling portion being inserted into the concave structure of the first TSV filling portion.

14. The wafer stacking structure of claim 13, further comprising:
at least one solder layer formed between the first TSV filling portion and the second TSV filling portion.

15. The wafer stacking structure of claim 14, wherein:
the solder layer includes a material selected from a group consisting of tin (Sn), nickel-gold alloy (NiAu), nickel-palladium-gold alloy (NiPdAu), tin-silver alloy (SnAg), and combinations thereof.

16. The wafer stacking structure of claim 13, further comprising:
a bonding pad surrounding at least one of the first and second TSV filling portions.

17. The wafer stacking structure of claim 16, wherein:
the bonding pad is formed of the same material as the at least one of the first and second TSV filling portions.

18. The wafer stacking structure of claim 13, further comprising:
a first barrier layer of Ta formed on side walls of the first TSV opening; and
a second barrier layer of CoWP formed on side walls of the second TSV opening.

19. The wafer stacking structure of claim 13, wherein:
a size of a minimum cross-sectional area of the concave structure is larger than or the same as a size of a maximum cross-sectional area of the convex structure.

20. The wafer stacking structure of claim 13, wherein:
the first wafer having the concave structure is stacked on top of the second wafer having the convex structure.

21. The wafer stacking structure of claim 13, wherein:
the second wafer having the convex structure is stacked on top of the first wafer having the concave structure.

22. The wafer stacking structure of claim 13, wherein:
each one of the first and second TSV filling portions includes at least one of a conductive material selected from a group consisting of copper (Cu), silver (Ag), gold (Au), tungsten (W), polysilicon, and combinations thereof.

23. A method of manufacturing a wafer, comprising:
forming a through silicon via (TSV) opening on the wafer; and
filling a conductive material in the opening by electroplating to form a TSV filling portion having a concave structure or a convex structure.
